(19) United States
(12) Patent Application Publication
(10) Pub. No.: US 2005/0225935 A1
(43) Pub. Date: Oct. 13, 2005

(54) Computer switch

(76) Inventor: Sun-Chung Chen, Hsi Chih City (TW)

Correspondence Address: Keith Kline;PRO-TECHTOR INTERNATIONAL, 20775 Norada Court, Saratoga, CA, 95070-3018, US

(21) Appl. No.: 10/875,631

(22) Filed: Jun. 23, 2004

(30) Foreign Application Priority Data
Apr. 7, 2004 (TW) 93205326

(51) Int. Cl. H05K 5/00

(52) U.S. Cl. 361/683

(57) ABSTRACT

A keyboard, video, mouse, and storage (KVMS) switch is described. The KVMS switch has a server computer interface, a keyboard-mouse-monitor interface, a storage device, and a control device. The server computer interface connects to at least one server computer and the keyboard-mouse-monitor interface connects to a keyboard, a mouse, and a monitor. The storage device with data stored therein is configured inside the KVMS to update and install software for the server computers. Therefore, the security and efficiency of server computer management are enhanced.

### FIELD OF THE INVENTION

The present invention relates to a computer switch and especially to a computer switch with an internal storage device.

### BACKGROUND OF THE INVENTION

Due to highly developed information technology, electrical and information products are more popular and convenient for users. Computer systems and peripherals thereof progress greatly, day by day, and people can search for information and provide services with networks. Via networks, people enjoy a comfortable and fast information search environment.

The wide proliferation of personal computers and networks allows people to utilize networks to search for and provide information. Therefore, using a network to search for information has become an ordinary skill for present modern people. Currently, network requests are higher, and network-related enterprises have to buy large numbers of computers and a lot of network equipment to satisfy user requests. For example, Internet service providers and virtual host providers need to buy large numbers of server computers to rent to users. Because these providers supply a fast network environment, a lot of companies are willing to rent their servers. The management and trouble shooting of these computers may become an important link. A large server provider has thousands of server computers. Control of each of these computers requires a monitor, a keyboard and a mouse. Actually, each of these computers spends little time on the monitor, keyboard and mouse. Most of the time, the servers need no peripheral devices for control. Control of every computer with a set of these peripheral devices would incur high operation costs and is not necessary. Such peripheral devices also waste space. In resolution of these problems, a computer switch with a monitor, a keyboard and a mouse can be utilized to control a plurality of server computers.

A conventional computer switch can control a number of server computers with merely a few monitors, mice, and keyboards. However, because computer software changes with each passing day, the server computers must be updated or computer software must be installed thereon. When the server computer is updated or new computer software is installed, the server computer has to utilize an internal or external input/output device, for example, an optical disk drive or a floppy drive, to read the data of the computer software. Therefore, the server computers are almost all equipped with a private input/output device, an internal optical disk drive or a floppy drive, to read/write data. The private input/output devices for the server computers are equipment reduplication and thus a waste.

### SUMMARY OF THE INVENTION

The conventional server computer utilizes a private input/output device to update or install the computer software. Therefore, there is not only hardware reduplication but also inconvenience for server computer management.

It is an objective of the present invention to provide a keyboard-video-mouse-storage device switch (KVMS switch) with an internal storage device switching together with the KVMS switch to provide the storage device to each of the server computers connected to the KVMS switch. Hence, the hardware cost of the server computers is reduced, and computer software updates and installation for the server computers are also convenient for the server computer supervisor.

To accomplish the above objectives, the present invention provides a KVMS switch. The KVMS switch has a server computer interface, a storage device, a keyboard-mouse-monitor interface, and a control device. The server computer interface connects to at least one server computer with at least one cable. The keyboard-mouse-monitor interface connects to a keyboard, a mouse, and a monitor with a control cable to control the at least one server computer. The storage device is configured in the KVMS switch to store data, e.g. computer software, for updating server computer data of the at least one server computer. The control device connects to the server computer interface, the keyboard-mouse-monitor interface, and the storage device for controlling the at least one server computer using the keyboard, the mouse, and the monitor. Further, the control device reads the data stored in the storage device for updating the server computer data.

The storage device is an optical disk drive, a card reader, a hard disk, and/or a flash disk. The cable connected between the KVMS switch and the server computers is a universal serial bus (USB) cable, an IEEE 1394 cable, or a small computer system interface (SCSI) cable.

The KVMS switch utilizes an internal storage device storing data to update and install software for the server computers connected with the KVMS switch. Therefore, management of the server computers is easy and the hardware cost of the server computers is also reduced. Furthermore, the internal storage device provides a stable data transmission for the server computer, and therefore the management of the server computers is safer and more efficient.

### BRIEF DESCRIPTION OF THE DRAWINGS

The foregoing aspects and many of the attendant advantages of this invention are more readily appreciated as the same becomes better understood by reference to the following detailed description, when taken in conjunction with the accompanying drawings, wherein:

FIG. 1 is a schematic diagram of a KVMS switch according to the present invention.

### DETAILED DESCRIPTION OF THE PREFERRED EMBODIMENT

The following description is of the best presently contemplated mode of carrying out the present invention. This description is not to be taken in a limiting sense but is made merely for the purpose of describing the general principles of the invention. The scope of the invention should be determined by referencing the appended claims.

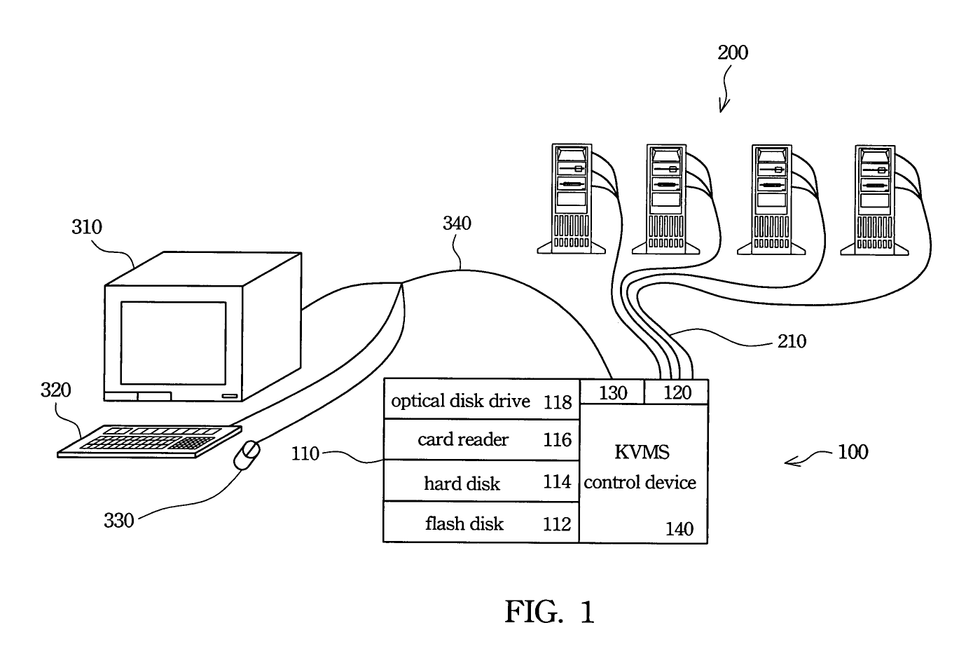

FIG. 1 is a schematic diagram of a KVMS switch according to the present invention. The KVMS switch 100 has a storage device 110, a server computer interface 120, a KVM interface 130, and a KVMS control device 140. The KVMS switch 100 utilizes cables 210 connecting the server computer interfaces 120 and server computers 200, and a cable 340 connecting the KVM interface 130 and a monitor 310, a keyboard 320, and a mouse 330.

The KVMS switch 100 according to the present invention utilizes the keyboard 320, mouse 330, and monitor 310 to control the server computers 200 and further utilizes the storage device 110 to provide data and software for updating of or installation on the server computers 200. Because the KVMS switch 100 has the keyboard 320, the mouse 330, the monitor 310, and the storage device 110, the KVMS switch 100 allows the server computer supervisor a convenient way to update or install the computer software stored in the storage device 110 on the server computers 200. Therefore, the server computers 200 need not have a similar private device installed therein to read and backup data. The storage device 110 is configured in the interior of the KVMS switch 100; hence the server computer supervisor need not move close to the server computers 200 to change the storage medium such as, for example, an optical disk. The server computer supervisor directly uses the storage device 110 to input/output data for the server computers 200. Accordingly, the KVMS switch 100 provides a convenient scheme for updating data for the server computers 200 from a remote position, and, further, the hardware costs of the server computers 200 can also be reduced.

The KVMS switch 100 utilizes an internal storage device 110 to provide data for the server computers 200. After the server computers 200 are connected to the KVMS switch 100, the internal storage device 110 of the KVMS switch 100 provides each of the server computers 200 with update data. Furthermore, the data transmission therebetween can also be more stable and safe due to the internal storage device 110 configured inside the KVMS switch 100. The KVMS switch 100 can further use a specific firmware installed in the control device 140 to allow friendly and convenient management of the storage device 110.

The storage device 110 is preferably a flash disk 112, a hard disk 114, a card reader 116 and/or an optical disk drive 118. Any other computer peripheral devices with data storage function are also applicable to the storage device 110 of the KVMS switch 100 to provide data and computer software for the server computers 200. The cables 210 are preferably a universal serial bus (USB) cable, an IEEE 1394 cable, or a small computer system interface (SCSI) cable.

The KVMS switch according to the present invention utilizes the internal storage device for to store data and update the computer software of the server computers connected with the KVMS switch. Therefore, the management of the server computers can be more convenient and the hardware cost of the server computers is also reduced. Furthermore, the internal storage device of the KVMS switch can provide a stable and safe data transmission between the KVMS switch and the server computers; hence the management of the server computers with the KVMS switch can be more safe and efficient.

As is understood by a person skilled in the art, the foregoing preferred embodiments of the present invention are illustrative of the present invention rather than limiting of the present invention. It is intended that various modifications and similar arrangements be included within the spirit and scope of the appended claims, the scope of which should be accorded the broadest interpretation so as to encompass all such modifications and similar structures.

1. A KVMS switch, comprising:
a server computer interface connecting with at least one server computer;
a keyboard-mouse-monitor interface connected to a keyboard, a mouse, and a monitor to control the at least one server computer;
a storage device configured in the KVMS switch to store data for updating server computer data of the at least one server computer; and
a control device connecting to the server computer interface, the keyboard-mouse-monitor interface, wherein the storage device controls the at least one server computer using the keyboard, the mouse, and the monitor and reads the data stored in the storage device for updating the server computer data.

2. The KVMS switch of claim 1, wherein the storage device comprises an optical disk drive.

3. The KVMS switch of claim 1, wherein the storage device comprises a card reader.

4. The KVMS switch of claim 1, wherein the storage device comprises a hard disk.

5. The KVMS switch of claim 1, wherein the storage device comprises a flash disk.

6. The KVMS switch of claim 1, wherein the KVMS switch utilizes at least one cable to connect to the at least one server computer.

7. The KVMS switch of claim 6, wherein the cable comprises a universal serial bus cable.

8. The KVMS switch of claim 6, wherein the cable comprises an IEEE 1394 cable.

9. The KVMS switch of claim 6, wherein the cable comprises a small computer system interface cable.

10. The KVMS switch of claim 1, wherein the data stored in the storage device comprises computer software for updating or installation of server computer software in the server computer.

11. A KVMS switch, comprising:
a server computer interface connected to at least one server computer;
a keyboard-mouse-monitor interface connected to a keyboard, a mouse, and a monitor to control the at least one server computer;
a storage device configured in the KVMS switch to store data for updating server computer data of the at least one server computer, wherein the storage device is an optical disk drive, a card reader, a hard disk, or a flash disk; and
a control device connecting to the server computer interface, the keyboard-mouse-monitor interface, and the storage device to control the at least one server computer using the keyboard, the mouse, and the monitor and to read the data stored in the storage device for updating the server computer data.

12. The KVMS switch of claim 11, wherein the KVMS switch utilizes at least one cable to connect to the at least one server computer.

13. The KVMS switch of claim 12, wherein the cable comprises a universal serial bus cable.

14. The KVMS switch of claim 12, wherein the cable comprises an IEEE 1394 cable.

15. The KVMS switch of claim 12, wherein the cable comprises a small computer system interface cable.

16. The KVMS switch of claim 11, wherein the data stored in the storage device comprises computer software for updating or installation of server computer software in the server computer.

17. A KVMS switch, comprising:
a server computer interface connecting to at least one server computer with a universal serial bus cable;
a keyboard-mouse-monitor interface connected to a keyboard, a mouse, and a monitor to control the at least one server computer;
a storage device configured in the KVMS switch to store data for updating server computer data of the at least one server computer, wherein the storage device is an optical disk drive, a card reader, a hard disk, or a flash disk; and
a control device connecting to the server computer interface, the keyboard-mouse-monitor interface, and the storage device to control the at least one server computer using the keyboard, the mouse, and the monitor and read the data stored in the storage device for updating the server computer data.

18. The KVMS switch of claim 11, wherein the data stored in the storage device comprises computer software for updating or installation of server computer software in the server computer.
